(19) United States
(12) Patent Application Publication
(10) Pub. No.: US 2010/0037959 A1
(43) Pub. Date: Feb. 18, 2010

(54) METHOD FOR SUPPLYING PROCESS GAS, SYSTEM FOR SUPPLYING PROCESS GAS, AND SYSTEM FOR PROCESSING OBJECT TO BE PROCESSED

(76) Inventors: Takayuki Kamaishi, Yamanashi-Ken (JP); Eiichi Komori, Yamanashi-Ken (JP); Susumu Yamauchi, Yamanashi-Ken (JP); Akifumi Hayashi, Mie-Ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/514,527

(22) PCT Filed: Nov. 13, 2007
(86) PCT No.: PCT/JP2007/072002

§ 371 Date: May 12, 2009

(30) Foreign Application Priority Data
Nov. 13, 2006 (JP) 2006-306109

(51) Int. Cl. H01L 21/67

(52) U.S. Cl. 137/14; 137/561 R

(57) ABSTRACT

A method of supplying a process gas comprises a step in which there is generated a process gas that is polymerizable depending on a temperature, and a step in which the thus generated process gas is supplied to a processing apparatus 4 configured to perform a predetermined process to an object to be processed W under a reduced-pressure atmosphere. When the process gas is supplied to the processing apparatus 4, a flow rate of the process gas is controlled by using a mass flow-rate control unit of a lower differential pressure type having a diaphragm 80, in which an appropriate operation range of a supply pressure is set lower than the atmospheric pressure. Thus, a supply rate (actual flow rate) of a process gas such as an HF gas that is polymerizable depending on a temperature can be precisely controlled in a stable manner.

### CROSS REFERENCE TO RELATED APPLICATIONS

This application is based upon and claims the benefit of priority from the prior Japanese Patent Application No. 2006-306109 filed on Nov. 13, 2006, the entire contents of which are incorporated herein by reference.

### FIELD OF THE INVENTION

The present invention relates to a method for supplying a process gas for supplying a process gas such as an HF gas (hydrogen fluoride gas) to an object to be processed such as a semiconductor wafer, a system for supplying such a process gas, and a system for processing an object to be processed.

### BACKGROUND ART

In order to manufacture such as a semiconductor integrated circuit, such as a semiconductor wafer formed of a silicon substrate or the like is generally subjected to various processes such as a film-deposition process, an etching process, an oxidation process, a diffusion process, and a process for removing a natural oxidation film. In particular, in an etching process for removing a natural oxidation film of a silicon substrate, and an etching process for removing another oxidation film, or a cleaning process for removing such as an unnecessary film adhered to such as an inner wall of a processing vessel used in a processing apparatus, an HF gas (hydrogen fluoride gas) is widely used as an etching gas (cleaning gas).

In this case, in order to perform a precise etching process (including a cleaning process, which is similar herebelow), it is necessary to precisely control the supply rate of an HF gas in a stable manner. In order to control the flow rate of an HF gas, there are commonly known a flow-rate control unit of a differential pressure type (JP2004-264881A etc.) and a mass flow-rate control unit such as a mass flow controller (JP2005-222173A etc.).

The flow-rate control unit of a differential pressure type is an apparatus that utilizes a feature in which, when a gas passing through an orifice is under a so-called critical condition, a flow rate of the gas at this moment is determined depending on a pressure on an upstream side of the orifice. On the other hand, the mass flow-rate control unit is an apparatus having therein a bendable diaphragm formed of a thin metal plate as a valve member, so as to control a valve opening degree by bending the diaphragm based on a detected heat quantity that moves in accordance with the movement of a gas flow.

Different from an inert gas such as a nitrogen gas and an He gas, the HF gas has a polymerizing property (also referred to as “clustering property”). Namely, an HF gas is polymerizable depending on a temperature and/or a pressure. For example, at a temperature not less than 70° C., HF molecules are separately present in the gas. On the other hand, at a temperature lower than 70° C., polymers of about (HF)₂ to (HF)₆ are present in the gas in a mixed manner. Thus, a molecular weight differs depending on a temperature.

In the flow-rate control unit of a differential pressure type, the flow rate is controlled such that the flow rate of a fluid is in proportion to a pressure on an upstream side of an orifice, and that a flow factor is in reverse proportion to the density of a gas in a standard condition. As described above, since the HF gas has the clustering property, a control circuit of the flow-rate control unit of a differential pressure type is required to store flow factors for each temperature and pressure which have been previously calculated.

In a general method of supplying an HF gas, the pressure of an HF gas at a high pressure, which is vaporized in a gas source stored in a liquid state, is reduced to about the atmospheric pressure (101 kPa), and the gas is made to flow. At an intermediate point of a flow channel, the flow rate of the gas is controlled by a flow-rate control unit, and the HF gas whose flow rate has been thus controlled is supplied into a substantially vacuum processing vessel. At this time, the pressure at which the gas is supplied actually varies about ±20 kPa. This complicates the control of the flow-rate control unit of a differential pressure type. In addition, when a pressure and/or a temperature changes, there is a possibility that the flow rate cannot be precisely controlled.

On the other hand, in the mass flow-rate control unit using a diaphragm, there is a possibility that, although a feedback control system for controlling a gas flow rate is normally operated, an actual flow rate of an HF gas that is controlled by the mass flow-rate control unit varies. In this case, it may be difficult to precisely control the supply rate (actual flow rate) of the HF gas. The reason therefor is considered as follows. Since the HF gas becomes a gas in which polymers are mixed, a gas specific heat required for detecting a gas flow rate changes, which influences a heat transfer amount of a flow rate detector. As a result, the detecting precision for detecting the mass flow rate is deteriorated.

As a countermeasure against the above problem, it is possible to continuously heat the overall mass flow-control unit at a temperature not less than 70° C. at which no polymerization of an HF gas occurs. However, in this case, since precision instruments around the semiconductor manufacturing apparatus may be thermally damaged, adoption of this measure is unpreferable.

### DISCLOSURE OF THE INVENTION

In view of the above problems, the present invention has been made so as to effectively solve the same. The object of the present invention is to provide a method for supplying a process gas, a system for supplying a process gas, and a system for processing an object to be processed, in which the supply rate (actual flow rate) of a process gas, such as an HF gas, which is polymerizable depending on a temperature can be precisely controlled in a stable manner.

As a result of the intensive examination of a method for supplying an HF gas, the inventors of the present invention found that the supply rate of the HF gas can be precisely controlled by controlling the flow rate of an HF gas by a mass flow-rate control unit using a diaphragm, under a supply pressure that is considerably lower than the atmospheric pressure. The present invention has thus been completed.

A method of processing a process gas according to the present invention comprises:

a step in which there is generated a process gas that is polymerizable depending on a temperature; and

a step in which the thus generated process gas is supplied to a processing apparatus configured to perform a predetermined process to an object to be processed under a reduced-pressure atmosphere;

wherein, when the process gas is supplied to the processing apparatus, a flow rate of the process gas is controlled by using a mass flow-rate control unit of a low differential pressure type having a diaphragm, in which an appropriate operation range of a supply pressure is set lower than the atmospheric pressure.

The flow rate of a process gas is controlled by using the mass flow-rate control unit of a low differential pressure type having a diaphragm, in which an appropriate operation range of a supply pressure is set lower than the atmospheric pressure. Thus, the supply rate (actual flow rate) of a process gas such as an HF gas that is polymerizable depending on a temperature can be precisely controlled in a stable manner.

In the method for processing a process gas according to the present invention, it is preferable that the appropriate operation range is between 5 kPa and 40 kPa.

In the method for processing a process gas according to the present invention, it is preferable that a temperature in the mass flow-rate control unit is set within a range between a temperature not less than 30° C. and a temperature lower than 70° C.

In the method for processing a process gas according to the present invention, it is preferable that the process gas is HF.

A system for supplying a process gas according to the present invention is a system for supplying a process gas configured to supply a process gas, which is polymerizable depending on a temperature, to a processing apparatus configured to perform a predetermined process to an object to be processed under a reduced-pressure atmosphere, the system comprising:

a gas supply channel connected to the processing apparatus;

a mass flow-rate control unit configured to control a flow rate of the process gas, the mass flow-rate control unit being disposed on the gas supply channel and having a diaphragm, in which an appropriate operation range of a supply pressure is set lower than the atmospheric pressure; and

a pressure control mechanism disposed on the gas supply channel at a position upstream of the mass flow-rate control unit, the pressure control mechanism being configured to control a process gas that has been supplied from a process gas source such that a pressure of the process gas falls within the appropriate operation range.

In the system for supplying a process gas according to the present invention, it is preferable that the appropriate operation range is between 5 kPa and 40 kPa.

In the system for supplying a process gas according to the present invention, it is preferable that a temperature in the mass flow-rate control unit is set within a range between a temperature not less than 30° C. and a temperature lower than 70° C.

In the system for supplying a process gas according to the present invention, it is preferable that the process gas is HF.

In the system for supplying a process gas according to the present invention, it is preferable that the diaphragm is provided with a ring-shaped bent part projecting on a side in opposition to the gas supply channel.

In the system for supplying a process gas according to the present invention, it is preferable that the diaphragm is of a partial spherical shell shape protruding on a side in opposition to the gas supply channel.

In the system for supplying a process gas according to the present invention, it is preferable that a valve port is formed in the gas supply channel at a position facing the diaphragm, that an actuator whose stroke can be varied is connected to the diaphragm on a side in opposition to the gas supply channel, that a diameter of the valve port is not less than 10 mm, and that a stroke amount of the actuator is not less than 20 μm.

A system for processing an object to be processed according to the present invention comprises:

a process gas source from which a process gas is supplied;

a gas supply channel connected to the process gas source,

a mass flow-rate control unit configured to control a flow rate of a process gas, the mass flow-rate control unit being disposed on the gas supply channel and having a diaphragm, in which an appropriate operation range of a supply pressure is set lower than the atmospheric pressure;

a pressure control mechanism disposed on the gas supply channel at a position upstream of the mass flow-rate control unit, the pressure control mechanism being configured to control a process gas that is supplied from the process gas source such that a pressure of the process gas falls within the appropriate operation range; and

a processing apparatus connected to the gas supply channel, the processing apparatus being configured to perform a predetermined process to an object to be processed under a reduced-pressure atmosphere.

According to the method for supplying the process gas, the system for supplying a process gas, and the system for processing an object to be processed can produce the following effects.

The flow rate of a process gas is controlled by using the mass flow-rate control unit of a low differential pressure type having a diaphragm in which an appropriate operation range of a supply pressure is set lower than the atmospheric pressure. Thus, the supply rate (actual flow rate) of a process gas such as an HF gas that is polymerizable depending on a temperature can be precisely controlled in a stable manner.

### BRIEF DESCRIPTION OF THE DRAWINGS

FIG. 1 is a schematic structural view showing an example of a system for processing an object to be processed including a system for supplying a process gas according to the present invention and a processing apparatus.

FIG. 2 is a schematic structural view showing an example of a mass flow-rate control unit of a low differential pressure type having a diaphragm, which is used in a processing system of a process gas according to the present invention.

FIG. 3A is a structural view showing a concrete example of the mass flow-rate control unit according to the present invention.

FIG. 3B is a structural view showing a concrete example of a conventional mass flow-rate control unit.

FIG. 4 is a graph showing a dependency of a supply pressure of the mass flow-rate control unit in which an appropriate operation range is set at about the atmospheric pressure (101 kPa).

FIG. 5 is a graph showing changes of conversion factors which are calculated with respect to the numerical values shown in FIG. 4.

FIG. 6 is a graph showing an evaluation result showing that the supply rate was controlled by using a mass flow-rate control unit in which an appropriate operation range was set between 5 kPa and 40 kPa.

### MODE FOR CARRYING OUT THE INVENTION

An embodiment of the method for supplying a process gas, the system for supplying a process gas, and the system for processing an object to be processed, according to the present invention, is described herebelow with reference to the accompanying drawings.

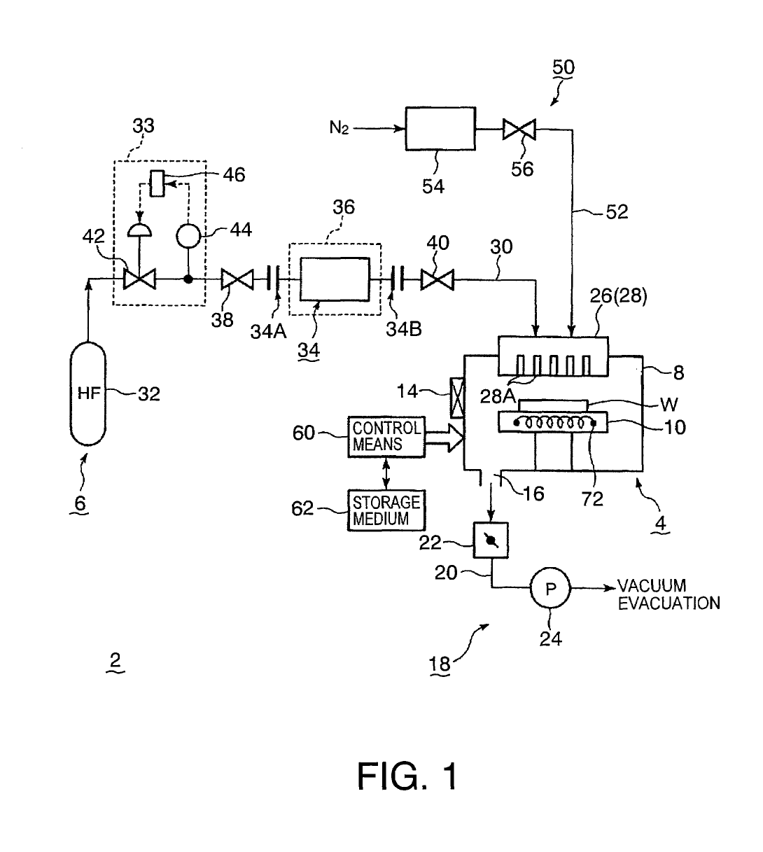

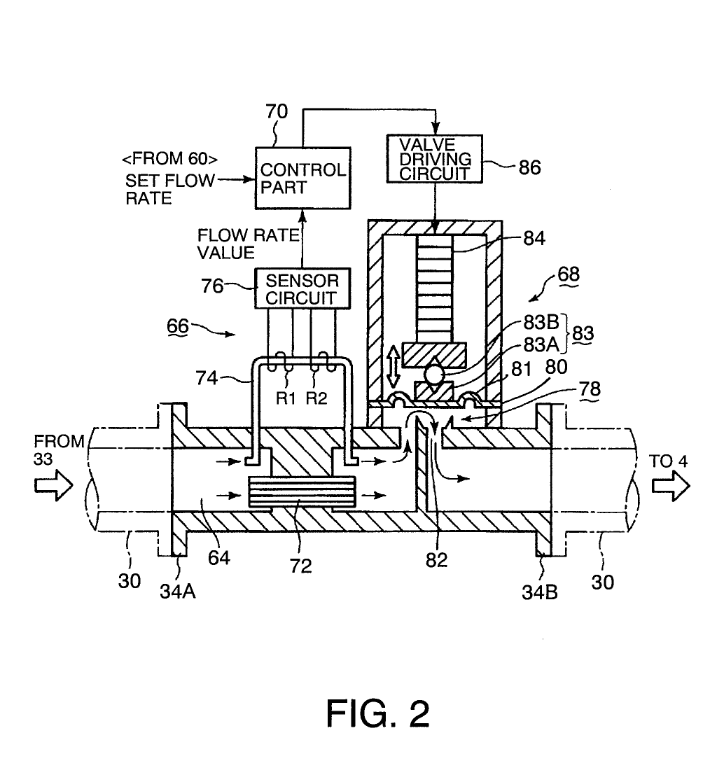

FIG. 1 is a schematic structural view showing an example of a system for processing an object to be processed including a system for supplying a process gas according to the present invention and a processing apparatus. FIG. 2 is a schematic structural view showing an example of a mass flow-rate control unit of a low differential pressure type having a diaphragm, which is used in a processing system of a process gas according to the present invention. Herein, as an example, used as a process gas is an HF gas which is polymerizable, or whose polymerization degree varies, depending on a pressure and/or a temperature. In addition, as an example, used as a processing apparatus is an etching apparatus that performs an etching process to an object to be processed.

As shown in FIG. 1, a system for processing an object to be processed 2 is mainly composed of: a processing apparatus 4 configured to perform a predetermined process such as an etching process, to an object to be processed such as a semiconductor wafer W, under a reduced-pressure atmosphere; and a system for supplying a process gas 6 configured to supply an HF gas as a process gas to the processing apparatus 4.

The processing apparatus 4 includes a cylindrical processing vessel 8 made of an aluminum alloy. In the processing vessel 8, there is disposed a table 10 of, e.g., a discoid shape, which projects from the bottom of the vessel. A semiconductor wafer W can be placed on an upper surface of the table 10. A heating means 12 formed of, e.g., a resistance heater, is buried in the table 10, so that a wafer W on the table 10 can be heated. As the heating means 12, a plurality of heating lamps may be disposed below the table 10 in place of the resistance heater.

In a sidewall of the processing vessel 8, there is arranged a gate valve 14 which is opened and closed when a wafer W is loaded into and unloaded from the processing vessel 8. An exhaust port 16 is formed in the bottom of the vessel. A vacuum evacuation system 18 is connected to the exhaust port 16, so that an inside of the processing vessel 8 can be evacuated to a predetermined reduced-pressure atmosphere. Specifically, the vacuum evacuation system 18 has an exhaust channel 20 that is connected to the exhaust port 16. A pressure control valve 22 and a vacuum pump 24 etc. are disposed on the exhaust channel 20 in this order along a flowing direction of an exhaust gas. Thus, the inside of the processing vessel 8 can be evacuated as described above.

The processing vessel 8 is provided with a gas introducing part 26 that is configured to supply various required gases into the processing vessel 8. In this embodiment, a showerhead 28 serving as the gas inlet part 26 is arranged on a ceiling part of the processing vessel 8. Thus, various gases can be jetted into the processing vessel 8 through a number of gas-jetting holes 28A formed in a lower surface of the showerhead 28. Alternatively, not limited to the showerhead 28, a nozzle, for example, may be disposed as the gas introducing part 26. A shape of the gas introducing part 26 is not particularly limited.

On the other hand, the system for supplying a process gas 6 to be connected to the processing apparatus 4 is provided with a gas supply channel 30 that is connected to a gas inlet of the showerhead 28. To a proximal end of the gas supply channel 30, there is connected a process gas source 32 capable of containing HF as a process gas in a liquid state or in a compressed gas state, for example. A pressure control mechanism 33 and a mass flow-rate control unit 34 using a diaphragm are disposed on the gas supply channel 30 in this order from an upstream side toward a downstream side of a gas flow. The mass flow-rate control unit 34 has connection flanges 34A and 34B disposed on an upstream side and a downstream side of the mass flow-rate control unit 34. By means of the connection flanges 34A and 34B, the mass flow-rate control unit 34 is connected to the gas supply channel 30 at an intermediate position thereof (see, also FIG. 2).

An appropriate operation range of a supply pressure in the mass flow-rate control unit 34 is set lower than the atmospheric pressure. For example, the appropriate operation range is set between 5 kPa and 40 kPa. The structure of the mass flow-rate control unit 34 is described hereafter.

The whole mass flow-rate control unit 34 is accommodated in a thermostatic bath 36, for example. Thus, the mass flow-rate control unit 34 can be maintained at a predetermined temperature, e.g., between a temperature not less than 30° C. and a temperature lower than 70° C. An upstream-side on-off valve 38 and a downstream-side on-off valve 40 are disposed on the gas supply channel 30 at positions immediately near the upstream side and immediately near the downstream side of the mass flow-rate control unit 34.

On the other hand, the pressure control mechanism 33 disposed on the upstream side of the mass flow-rate control unit 34 has a vacuum pressure-reducing valve 42 disposed on the gas supply channel 30, and a pressure sensor 44, which is formed of a capacitance manometer, for example, disposed on the downstream side of the vacuum pressure-reducing valve 42. By controlling the vacuum pressure-reducing valve 42 by means of a pressure control part 46 based on an output of the pressure sensor 44, a supply pressure of the HF gas flowing from the upstream side at a supply pressure higher than the atmospheric pressure is reduced such that the supply pressure falls within the appropriate operation range.

An inert-gas supply system 50 is connected to the showerhead 28. Specifically, the inert-gas supply system 50 has a gas pipe 52 that is connected to the showerhead 28. The gas pipe 52 is equipped with a flow rate controller 54 such as a mass flow controller and an on-off valve 56, in this order. Thus, an N₂ gas, for example, can be supplied into the processing vessel 8 as a purge gas or a diluent gas. Alternatively, a rare gas such as He and Ar may be used in place of N₂.

Control of the overall processing system 2 as structured above, e.g., start and stop of the supply of various gases, and control of a gas flow rate, a pressure, and a temperature, are performed by a control means 60 formed of a microcomputer, for example. The control means 60 includes a storage medium 62 formed of, e.g., a flexible disc, a hard disc, a CD-ROM, a DVD, and a flash memory, which stores a program for controlling all the operations of the apparatus.

Next, there is described a mass flow-rate control unit 34 of a low differential pressure type which is used in the system for supplying a process gas 6 with also reference to FIG. 2. The mass flow-rate control unit 34 is mainly composed of: a duct 64 made of, e.g., a stainless steel, which is directly connected to the gas supply channel 30; a mass flow-rate detecting part 66 that detects a mass flow rate of a fluid (gas); a flow-rate control valve mechanism 68 that controls a flow of the gas; and a control part 70 that controls an operation of the overall mass flow-rate control unit 34 under control of the control means 60. A flow rate of the gas is controlled such that the flow rate conforms to a set flow rate which is inputted by the control means 60.

To be specific, the mass flow-rate detecting part 66 includes a bypass group 72 having a bunch of bypass pipes, the bypass group 72 being disposed on the upstream side of the duct 64. A sensor pipe 74 is connected to opposed end sides of the bypass group 72 such that the sensor pipe 74 bypasses the bypass group 72. Thus, a gas flows through the sensor pipe 74 at a constant flow rate that is smaller than a flow rate of the gas flowing through the bypass group 72.

The sensor pipe 74 is wound with a pair of control resistance wires R1 and R2. A flow rate value detected by a sensor circuit 76, which is connected to the resistance wires R1 and R2, can be outputted. In the sensor circuit 76, a bridge circuit is formed by the resistance wires R1 and R2, and two reference resistances, not shown.

Thus, when a gas, which has been heated by a heat of the resistance wire R1 positioned on the upstream side of the sensor pipe 74, flows downstream, a heat is moved so that the resistance wire R2 on the downstream side is heated by a heat quantity corresponding to the gas flow rate at this moment. As a result, by taking out a resistance change of the downstream resistance wire R2 at this moment as a change of an electric potential, a flow rate of the gas flowing at this moment can be measured.

On the other hand, the flow-rate control valve mechanism 68 includes a flow-rate control valve 78 that is disposed on the downstream side of the bypass group 72. The flow-rate control valve 78 is provided with a bendable diaphragm 80 made of a metal plate as a valve member for directly controlling a flow rate of a gas. The diaphragm 80 has a ring-shaped bent part 81 having a semicircular arc shape in cross-section. By suitably bending and deforming the diaphragm 80 toward a valve port 82, a valve opening degree of the valve port 82 can be controlled.

On a side surface opposed to the diaphragm 80 (a top surface of the diaphragm 80), there is disposed an actuator 84 via a connection member 83 formed of, e.g., a push base 83A and a rigid ball 83B. By a driving signal from a valve driving circuit 86, an expansion and contraction stroke amount of the actuator 84 can be controlled. The actuator 84 is formed of, e.g., a laminated piezoelectric element. The valve driving circuit 86 is operated by a driving command from the control part 70, and thus a flow rate of a gas can be feedback-controlled.

In the mass flow-rate control unit 34 as structured above, it is known that a precision of controlling a flow rate of a gas flowing from the upstream side is largely varied by a pressure at which the gas is supplied. Thus, a general mass flow-rate control unit is designed such that a supply rate of a gas flowing downstream can be precisely controlled when a supply pressure of the gas flowing from the upstream side is about the same as the atmospheric pressure. That is to say, in the general mass flow-rate control unit, an appropriate operation range of the supply pressure is designed to be about the same as the atmospheric pressure. On the other hand, in the mass flow-control unit 34 used in the present invention, an appropriate operation range of the supply pressure is designed to be lower than the atmospheric pressure. Specifically, the appropriate operation range is between 5 kPa and 40 kPa, preferably between 10 kPa and 30 kPa. By setting the appropriate operation range of the supply pressure to be lower than the atmospheric pressure, the flow rate of an HF gas can be precisely controlled at relatively a lower temperature.

A mass flow-rate control unit, in which an appropriate operation range of a supply pressure is set to be lower than the atmospheric pressure, is generally manufactured, by optimizing a diameter of the valve port 82, a stroke amount (valve opening degree) of the actuator 84, and a diameter of the diaphragm 80, for example. As the mass flow-rate control apparatus 34, there may used such as SFC1571FAMO-4UGLN (machine name) in SFC1571 series manufactured by Hitachi Metals, Ltd.

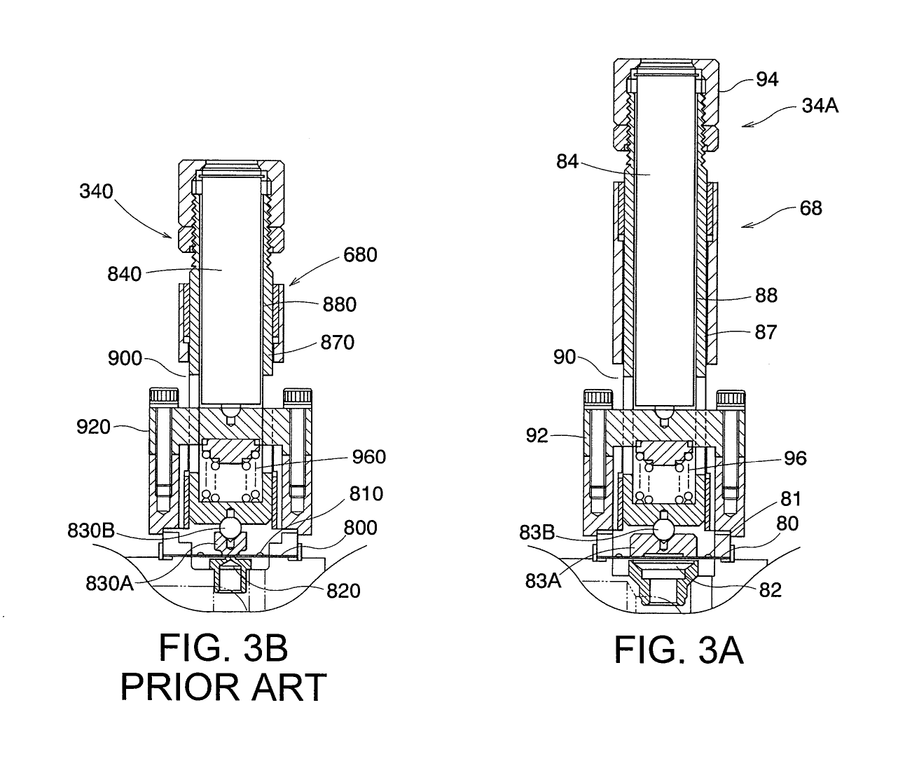

The aforementioned mass flow-rate control unit is concretely described as compared with a conventional mass flow-rate control unit. FIG. 3 shows a concrete example of a mass flow-rate control unit according to the present invention, and a concrete example of a conventional mass flow-rate control unit.

FIG. 3A shows an embodiment of a mass flow-rate control unit according to the present invention in which an appropriate operation range of a supply pressure is set to be lower than the atmospheric pressure. Herein, elements equivalent to those shown in FIG. 2 are denoted by the same reference numbers. FIG. 3B shows a conventional mass flow-rate control unit having the same flow rate range as that of the mass flow-rate control unit shown in FIG. 3A. In FIG. 3B, elements equivalent to those of the present invention are denoted by the reference numbers in FIG. 3A to which “0” is added.

As shown in FIG. 3A, in the mass flow-rate control unit 34, a diameter of the valve port 82 is set to be φ12.4 mm, a stroke amount of the actuator 84 is set to be about 30 μm, and a flow rate range is set to be 200 cc/min.

On the other hand, in the conventional mass flow-rate control unit 340 shown in FIG. 3B, a flow rate range is set to be 200 cc/min, which is the same as that of the unit of the present invention, a diameter of the valve port 820 is set to be φ0.6 mm, and a stroke amount of the actuator 840 is set to be about 20 μm.

Namely, in the conventional mass flow-rate control unit 340, even when a pressure of a part on the downstream side of a gas flow is reduced to create a vacuum, a pressure on the upstream side of the valve port 820 cannot reach a required vacuum pressure, because the valve port 820 serves as an orifice plate. As a result, the HF gas passes through the bypass group and the sensor pipe etc. constituting the mass flow-rate detecting part, without the HF molecules becoming mono-molecules. Thus, it is difficult to precisely control the flow rate.

On the other hand, in the mass flow-rate control unit 34 according to the present invention, the diameter of the valve port and the stroke amount of the actuator are set to be about 20 times and about 1.5 times those of the conventional mass flow-rate control unit 340. Thus, there is provided a mass flow-rate control unit of a low differential pressure type in which a difference between a pressure on the upstream side of the valve port 82 and a pressure on the downstream side thereof is rarely generated. In this mass flow-rate control unit of a low differential type, since a part up to the upstream side of the valve port 82 can be set at a required vacuum pressure, the HF molecules in the HF gas become mono-molecules, which makes possible a precise flow rate control.

In this case, it is preferable that the diameter of the valve port 82 is set to be, at least, 10 mm or more, and that the stroke amount of the actuator 84 is set to be 20 μm or more.

The diaphragm 80 is configured to be capable of being appropriately operated at a supply pressure that is lower than the atmospheric pressure. Namely, when the inside of the duct 64 is set at a vacuum pressure, the diaphragm 80 is subjected to the atmospheric pressure on the side of the actuator 84. Namely, the diaphragm 80 is subjected to a pressure urging the diaphragm 80 toward the valve port 82. However, the diaphragm 80 has a self recovery resilient force toward the actuator 84 because of the bent part 81 that circularly projects. Thus, when the diaphragm 80 is subjected to the atmospheric pressure, the valve opening degree can be precisely maintained, because the diaphragm 80 will not be displaced toward the valve port 82. Accordingly, the diaphragm 80 can precisely maintain the valve opening degree, and is thus suitable for controlling a flow rate under a vacuum pressure.

The valve port 82 is a valve port that is enlarged upward in the drawings in a tapered manner so as to be in contact with the diaphragm 80 near the bent part 81. Since the valve port 82 is positioned near the bent part 81, an operational displacement of the diaphragm 80 can be further stabilized.

In this embodiment, the diaphragm 80 has the bent part 81 so as to be appropriately operated at a supply pressure lower than the atmospheric pressure. However, the diaphragm 80 may have a partial spherical shell shape protruding upward in the drawings, for example. In this case, by decreasing a curvature of the spherical shell, or by providing a plurality of diaphragms, an appropriate operation at a supply pressure lower than the atmospheric pressure can be realized.

FIG. 2 shows a so-called normally opened type in which a valve is opened at a maximum opening degree when the unit is not controlled. However, as shown in FIG. 3A, a so-called normally closed type is possible in which a valve is closed when the unit is not controlled.

In the mass flow-rate control unit shown in FIG. 3A, the pushing base 83A and the rigid ball 83B are arranged in opposition to the diaphragm 80, and the rigid ball 83B is in contact with a valve rod 87. The valve rod 87 includes therein a hollow space 88, and is provided with a through-hole 90 passing through the hollow space 88 and an outer surface of the valve rod 87.

There is provided a bridge 92 passing through the through-hole 90 of the valve rod 87, with opposed ends of the bridge 92 being fixed on a body of the flow-rate control valve mechanism 68. The bridge 92 receives a lower end of the actuator 84 such that the lower end cannot be moved in the up and down direction. On the other hand, an upper end of the actuator 84 is supported by the valve rod 87 via an adjustment member 94. Between the valve rod 87 and the bridge 92, there is disposed a coil spring 96 as an urging means for urging the valve rod 87 downward. For example, the actuator 84 is formed by stacking three laminated piezoelectric elements, having a length of about 20 mm. The laminated piezoelectric element will be extended when an electric voltage is applied to the actuator 84.

Thus, when no electric voltage is applied to the actuator 84, the valve rod 87 is pressed downward by the urging force of the coil spring 96, so that the flow-rate control valve mechanism 68 is in a closed condition. When an electric voltage is applied to the actuator 84, the actuator 84 is extended substantially in proportion to the electric voltage, so that the valve rod 87 is moved upward against the urging force of the coil spring 96. Thus, the valve opening degree of the flow-rate control valve mechanism 68 can be adjusted so as to control a flow rate.

Next, there is described an etching process performed by the system for processing an object to be processed 2 as structured above.

At first, the gate valve 14 of the processing apparatus 4 is opened, and loaded into the processing vessel 8 is a semiconductor wafer W to which surface a silicon natural oxidation film or the like is adhered.

Then, the vacuum exhaust system 18 is driven to evacuate an atmosphere in the processing vessel 8 so as to maintain the processing vessel 8 at a predetermined process pressure, and the wafer W is heated by the heating means 12 to a predetermined process temperature and maintained thereat. At the same time, an HF gas is supplied from the system for supplying a process gas 6, with a flow rate of the HF gas being controlled. The HF gas is introduced into the processing vessel 8 through the showerhead 28, so as to perform an etching process for removing the natural oxidation film on the wafer surface.

A concrete operation of the system for supplying a process gas 6 is described. At first, an HF gas is supplied from the process gas source 32 at a pressure that is about the same as the atmospheric pressure or larger, and the HF gas flows through the gas supply channel 30. Then, the supply pressure of the HF gas is reduced by the vacuum pressure-reducing valve 42 of pressure control mechanism 33 to a predetermined pressure, i.e., to a range between 5 kPa and 40 kPa that is the appropriate operation range of the supply pressure in the mass flow-rate control unit 34. Then, a flow rate (supply rate) of the HF gas whose supply pressure has fallen within the appropriate operation range is controlled by the mass flow-rate control unit 34, and the HF gas flows toward the downstream processing apparatus 4.

At this time, the overall mass flow-rate control unit 34 is heated by the thermostatic bath 36, if necessary, to a temperature ranging from a temperature not less than 30° C. to a temperature lower than 70° C., preferably from 40° C. to 60° C. When the mass flow-rate control unit 34 is heated at 70° C. or more, there is a possibility that the precision instruments around the unit etc. are undesirably damaged. On the other hand, when the temperature in the mass flow-rate control unit 34 is lower than 30° C., there is a possibility that a polymerization degree of the HF gas is rapidly increased, so that the flow-rate control precision may be considerably, undesirably deteriorated.

As described above, since a flow rate of a process gas is controlled with the use of the mass flow-rate control unit 34 of a low differential pressure type having a diaphragm, in which an appropriate operation range of a supply pressure is lower than the atmospheric pressure, a supply rate (actual flow rate) of the process gas such as an HF gas that is polymerizable depending on a temperature can be precisely controlled in a stable manner.

<Evaluation of System for Supplying Process Gas according to Present Invention>

Next, an evaluation test was conducted in which an HF gas was made to actually flow with a flow rate thereof being controlled by the system for supplying a process gas according to the present invention, and the evaluation result is described.

[Mass Flow-Rate Control Unit in which Appropriate Operation Range is about the Same as Atmospheric Pressure]

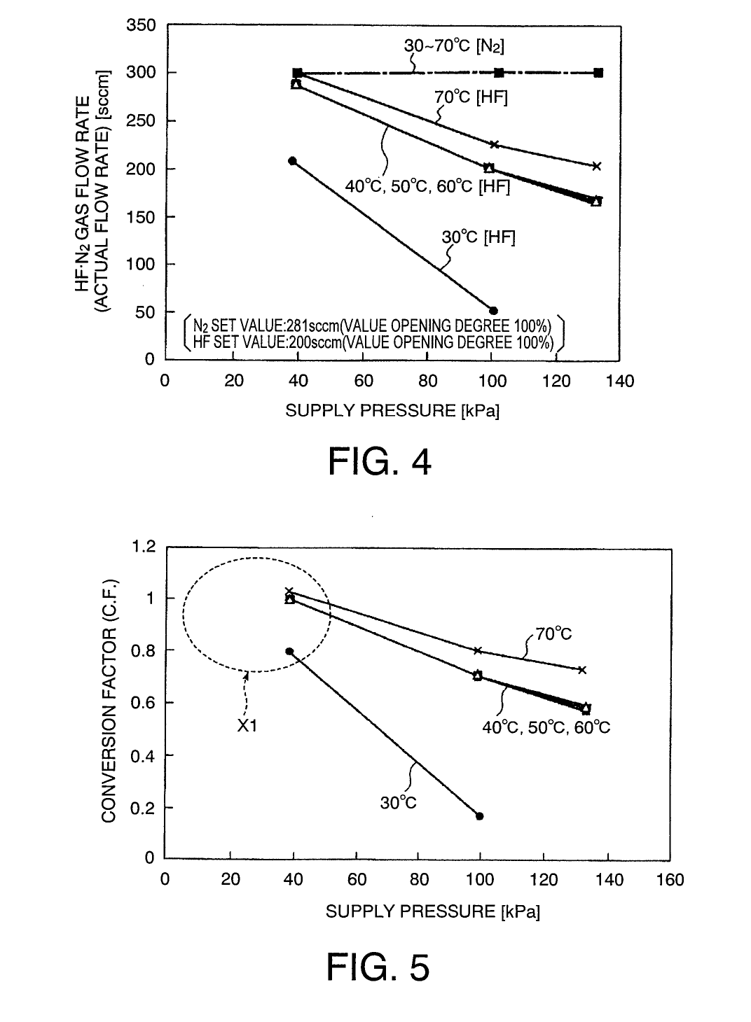

As a comparison example, a dependency of a supply pressure was evaluated for a mass flow-rate control unit in which an appropriate operation range is set at about the atmospheric pressure (101 kPa). FIG. 4 is a graph showing a dependency of a supply pressure in a mass flow-rate control unit in which an appropriate operation range is set at about the atmospheric pressure (101 kPa).

For comparison, there was conducted a test in which an N₂ gas that is not polymerizable depending on a pressure and/or a temperature was measured. Herein, the axis of abscissa shows a gas supply pressure, and the axis of ordinate shows a flow rate (actual flow rate) of the HF gas and the N₂ gas. Temperatures in the mass flow-rate control unit itself were set at 40° C., 50° C., 60° C., and 70° C. A set flow-rate value of the HF gas was 200 sccm (valve opening degree: 100%), and a set flow-rate value of the N₂ gas was 281 sccm (valve opening degree: 100%).

As apparent from FIG. 4 with respect to the HF gas supplied at a pressure of 100 kPa, the HF gas flow rate was 200 sccm which is the same as the set value, when the temperature was between 40° C. and 60° C. When the supply pressure was varied within a range between 40 kPa and 135 kPa, as the supply pressure was increased, the HF gas flow rate (actual flow rate) was gradually, linearly decreased. Thus, it could be confirmed that the flow-rate control precision was deteriorated depending on the change of the supply pressure of the HF gas. In addition, when the temperatures of the unit itself were varied to 40° C., 50° C., and 60° C., the gas flow rates were substantially the same. However, when the temperature of the unit was 30° C., the gas flow rate was rapidly and significantly decreased.

On the other hand, in a case where the temperature of the unit was 70° C., the gas flow rate was substantially the same as those in the cases where the temperature of the unit was from 40° C. to 60° C., when the supply pressure was 40 kPa. However, it could be confirmed that, as the supply pressure was increased, the flow rate difference was gradually varied in a flow-rate increase direction (+ direction) from the curve obtained when the temperature was from 40° C. to 60° C. Since the supply pressure is set at about the atmospheric pressure, C.F. (conversion factor) is set at “0.711”.

On the other hand, it can be understood that a flow rate of the N₂ gas, which is not associatable or polymerizable regardless of a pressure and/or a temperature, can be precisely controlled at an actual flow rate of about 281 sccm over all the range of the supply pressure between 40 kPa and 135 kPa.

[Evaluation of Conversion Factor]

Then, an evaluation test was conducted in which conversion factors were calculated with respect to the values shown in FIG. 4, and the evaluation result is described. FIG. 5 is a graph showing changes of conversion factors which are calculated with respect to the numerical values shown in FIG. 4. As show in the following equation, the conversion factor (C.F.) is represented by a ratio of the flow rate of the HF gas relative to the flow rate of the N₂ gas. The conversion factor is an element that shows a dependency of a temperature and a pressure of gases used in the mass flow-rate control unit.

C.F.=HF gas flow rate/N₂ gas flow rate

As shown in FIG. 5, the curves at the temperatures of 30° C., 40° C., 50° C., 60° C., and 70° C. have substantially the same tendency as those shown in FIG. 4. Namely, it can be understood that, as the supply pressure is decreased, the curves tend to gather to an upper left part of the graph, and to meet at an area X1 in which the supply pressure is not more than 40 kPa and the conversion factor is “1.0”.

This means that, in an area in which the gas supply pressure is lower, i.e., not more than 40 kPa, there is a part in which the actual flow rate of the gas is insensitive to the supply pressure of the gas. Namely, there is a part in which the actual flow rate of the gas is not dependent on the supply pressure, or a part in which the actual flow rate of the gas is scarcely dependent on the supply pressure. That is to say, this means that, at an area in which C.F=1, the supply rate of the N₂ gas and the supply rate of the HF gas equal to each other.

Thus, in the present invention, as has been described above, a flow rate of an HF gas is controlled by using the mass flow-rate control unit 34 of a low differential pressure type, in which an appropriate operation range of a supply pressure of the gas is set in a range between 5 kPa and 40 kpa, and C.F. is set at “1”.

[Mass Flow-Rate Control Unit in which Appropriate Operation Range is Set Between 5 kPa and 40 kPa]

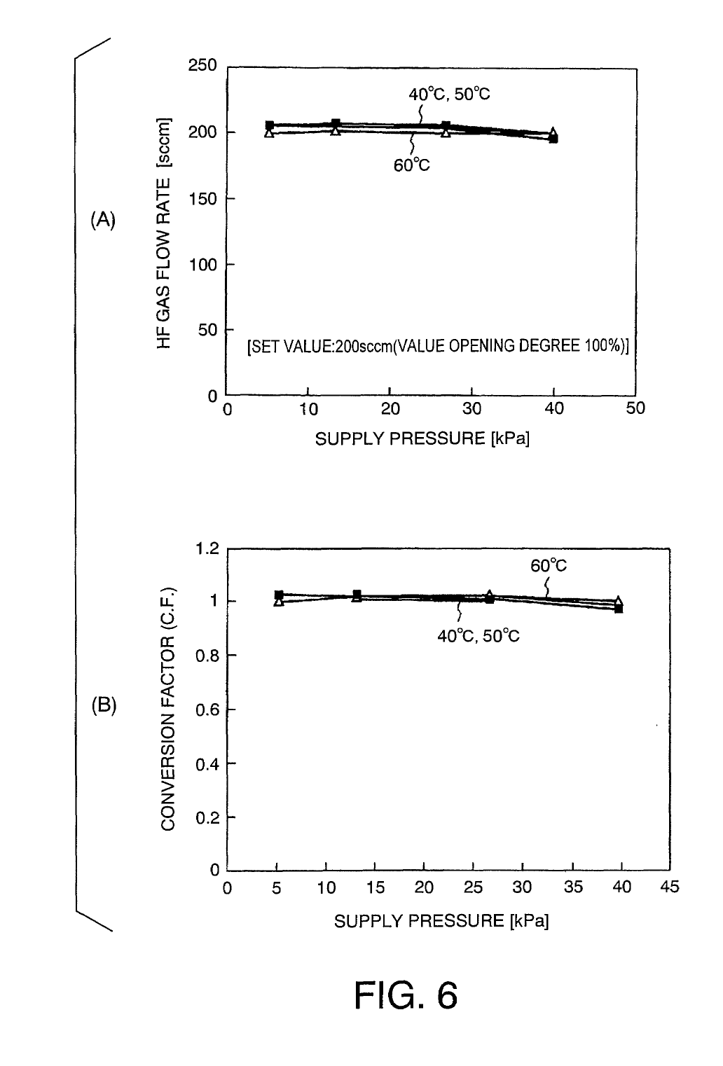

FIG. 6 is a graph showing an evaluation result showing that a supply rate was controlled by using a mass flow-rate control unit in which an appropriate operation range was set between 5 kPa and 40 kPa. FIG. 6(A) is a graph showing a relationship between the supply pressure and the HF gas supply rate (actual flow rate), and FIG. 6(B) is a graph showing conversion factors calculated based on the numerical values shown in FIG. 6(A). A set value of the supply rate of the HG gas was 200 sccm (valve opening degree: 100%). The temperatures in the mass flow-rate control unit 34 were set at 40° C., 50° C., and 60° C.

As apparent from FIG. 6(A), even when the supply pressure of the HF gas was varied within a range between 5 kPa and 40 kPa, the supply rate (actual flow rate) of the HF gas indicated about 200 sccm at the all temperatures of 40° C., 50° C., and 60° C. As shown in FIG. 6(B), the C.F. at each temperature indicated about “1”. Thus, it could be confirmed that the flow rate of the HF gas could be precisely controlled in a stable manner.

In this case, when the supply pressure of the gas is under 5 kPa, the supply rate of the gas per unit time is excessively decreased, which is not practical. On the other hand, when the supply pressure of the gas is larger than 40 kPa, a control precision of the actual flow rate is deteriorated. Judging from the graph shown in FIG. 6(A), a more preferred range of the supply pressure of the gas is between about 10 kPa and about 30 kPa.

In the aforementioned embodiment, an example to describe this present invention is a case where an etching process for removing a natural oxidation film is performed. However, not limited thereto, the present invention can be applied to all the processes in which an HF gas is used.

In addition, a gas to be used is not limited to an HF gas, and the present invention can be applied to all the gases that is associatable (polymerizable) depending on a temperature and/or a pressure.

Further, the processing apparatus of a wafer-fed type has been described in this embodiment referring to FIG. 1. However, such a processing apparatus is merely an example, and the present invention is naturally not limited thereto. Namely, the present invention can be applied to a processing apparatus of a batch type in which a plurality of wafers can be simultaneously processed.

Furthermore, a semiconductor wafer is taken as an example of an object to be processed. However, not limited thereto, the present invention can be applied to a glass substrate, an LCD substrate, a ceramic substrate and so on.

1. A method for supplying a process gas, the method comprising:
a step in which there is generated a process gas that is polymerizable depending on a temperature; and
a step in which the thus generated process gas is supplied to a processing apparatus configured to perform a predetermined process to an object to be processed under a reduced-pressure atmosphere;
wherein, when the process gas is supplied to the processing apparatus, a flow rate of the process gas is controlled by using a mass flow-rate control unit of a low differential pressure type having a diaphragm, in which an appropriate operation range of a supply pressure is set lower than the atmospheric pressure.

2. The method for supplying a process gas according to claim 1, wherein
the appropriate operation range is between 5 kPa and 40 kPa.

3. The method for supplying a process gas according to claim 1, wherein
a temperature in the mass flow-rate control unit is set within a range between a temperature not less than 30° C. and a temperature lower than 70° C.

4. The method for supplying a process gas according to claim 1, wherein
the process gas is HF.

5. A system for supplying a process gas configured to supply a process gas, which is polymerizable depending on a temperature, to a processing apparatus configured to perform a predetermined process to an object to be processed under a reduced-pressure atmosphere, the system comprising:
a gas supply channel connected to the processing apparatus;
a mass flow-rate control unit configured to control a flow rate of the process gas, the mass flow-rate control unit being disposed on the gas supply channel and having a diaphragm, in which an appropriate operation range of a supply pressure is set lower than the atmospheric pressure; and
a pressure control mechanism disposed on the gas supply channel at a position upstream of the mass flow-rate control unit, the pressure control mechanism being configured to control a process gas that has been supplied from a process gas source such that a pressure of the process gas falls within the appropriate operation range.

6. The system for supplying a process gas according to claim 5, wherein
the appropriate operation range is between 5 kPa and 40 kPa.

7. The system for supplying a process gas according to claim 5, wherein
a temperature in the mass flow-rate control unit is set within a range between a temperature not less than 30° C. and a temperature lower than 70° C.

8. The system for supplying a process gas according to claim 5, wherein
the process gas is HF.

9. The system for supplying a process gas according to claim 5, wherein
the diaphragm is provided with a ring-shaped bent part projecting on a side in opposition to the gas supply channel.

10. The system for supplying a process gas according to claim 5, wherein
the diaphragm is of a partial spherical shell shape protruding on a side in opposition to the gas supply channel.

11. The system for supplying a process gas according to claim 5, wherein
a valve port is formed in the gas supply channel at a position facing the diaphragm,
an actuator whose stroke can be varied is connected to the diaphragm on a side in opposition to the gas supply channel,
a diameter of the valve port is not less than 10 mm, and
a stroke amount of the actuator is not less than 20 μm.

12. A system for processing an object to be processed, the system comprising:
a process gas source from which a process gas is supplied;
a gas supply channel connected to the process gas source,
a mass flow-rate control unit configured to control a flow rate of a process gas, the mass flow-rate control unit being disposed on the gas supply channel and having a diaphragm, in which an appropriate operation range of a supply pressure is set lower than the atmospheric pressure;
a pressure control mechanism disposed on the gas supply channel at a position upstream of the mass flow-rate control unit, the pressure control mechanism being configured to control a process gas that is supplied from the process gas source such that a pressure of the process gas falls within the appropriate operation range; and
a processing apparatus connected to the gas supply channel, the processing apparatus being configured to perform a predetermined process to an object to be processed under a reduced-pressure atmosphere.
